(19) United States
(12) Patent Application Publication
(10) Pub. No.: US 2002/0023841 A1
(43) Pub. Date: Feb. 28, 2002

(54) Electrohydrodynamic convection microfluidic mixer

(76) Inventors: Chong H. Ahn, Cincinnati, OH (US); Jin-Woo Choi, Cincinnati, OH (US)

Correspondence Address: FROST BROWN TODD LLC, 2200 PNC Center, 201 East Fifth Street, Cincinnati, OH, 45202, US

(21) Appl. No.: 09/871,718

(22) Filed: Jun. 1, 2001

Related U.S. Application Data
(60) Provisional application No. 60/209,051, filed on Jun. 2, 2000.

(51) Int. Cl. G01N 27/26; G01N 27/447

(52) U.S. Cl. 204/547; 204/451; 204/601; 204/643

(57) ABSTRACT

The present invention provides a novel active micro-mixer device and methods using electrohydrodynamic (EHD) convection. At least two fluid samples are introduced into a microchannel device wherein the surface charges are induced at the interface of the liquid samples that have different electric conductivities, and these surface charges react with applied electric fields to generate electric shear forces. By applying electric fields, the separate flow streams get mixed passing the electrodes. A new active micro-mixer for liquid/liquid mixing has been designed, fabricated, and demonstrated by flowing two liquid samples through the microchannel. The device can be used in the nano- or pico-liter range of liquid volumes by applying a low voltage across the microchannel. The micro-mixing device invented in this work has simple structure and no mechanical moving part, which can provide a reliable mixing function on biochips.

### RELATED APPLICATIONS

This invention claims priority of U.S. Provisional Patent Appl. Ser. No. 60/209,051, filed Jun. 2, 2000, incorporated herein by reference.

This invention was made in part with Government support under Grant No. AF F 30602-97-2-0102, awarded by the Defense Advanced Research Projects Agency. The Government may have certain rights in this invention.

### FIELD OF THE INVENTION

The present invention provides an active microfluidic mixer for mixing of liquid samples using electrohydrodynamic (EHD) convection for applications in microfluidic-based biochemical analysis systems and biochips. A new active micro-mixer for liquid/liquid mixing has been designed, fabricated, and demonstrated by flowing two liquid samples through the microchannel. The device can be used in the nano- or pico-liter range of liquid volumes by applying a low voltage across the microchannel.

The present invention also pertains to methods of using such devices for the separation and analysis of biological materials for immunoassays, DNA sequencing, protein analysis and biochemical detection applications.

### BACKGROUND OF THE INVENTION

In microfluidic-based biochemical analysis systems, mixing of the liquid samples is considered as one of the most challenging tasks in order to achieve an appropriate reaction in a short period of time.

Mixing of the liquid samples is frequently required to increase reaction probability so as to improve the detection and analysis capability of micro total analysis systems for detection of biological molecules or for analyzing DNA in microfluidic systems. There are, however, some difficulties in realizing reliable micro mixing devices, because the fluid in microchannels shows as a laminar flow characteristic in most cases due to low Reynolds number. Mechanical stirring or agitating of the liquid samples usually achieves mixing of the liquid samples in macro- scale systems, but these methods are not feasible for micro-scale devices due to its small size and fabrication compatibility. For these reasons, several micro mixing devices have been recently developed and reported. Most of them are passive micro-mixers, but a few semi- active micro-mixers with enough mixing capabilities have been reported. Passive mixing devices can also be useful in micro total analysis systems (μ-TAS) and biochip applications, but they have limitations when precise control of mixing performances concerning mixing volume and time is required.

The electrohydrodynamic and magnetohydrodynamic (MHD) phenomena have been explored since early 1960's and there have been studies to realize the EHD and MHD micromixers. Both EHD and MHD phenomena are attractive when scaled down to micro levels, specifically for microfluidic control because of their simple structure in micro- and nano-scale fluidic control. In addition, since these EHD and MHD devices do not include mechanically moving parts, they provide more reliable mixing. Since the microfluidic mixer in this work has numerous advantages such as: simple structure, an active mixing characteristic and no mechanically moving parts, it has significant potential in microfluidic analysis systems and biochip applications.

The use of micromachining techniques to fabricate such analysis systems is often in silicon. Silicon provides the practical benefit of enabling mass production of such systems. A number of established techniques developed by the microelectronics industry using micromachining exist and provide accepted approaches to miniaturization. Examples of the use of such micromachining techniques are found in U.S. Pat. Nos. 5,194,133, 5,132,012, 4,908,112, and 4,891,120 incorporated herein by reference in their entirety.

### BRIEF SUMMARY OF THE INVENTION

The present invention provides a novel active micro-mixer using electrohydrodynamic (EHD) convection. At least two fluid samples are introduced into a microchannel device wherein the surface charges are induced at the interface of the liquid samples that have different electric conductivities, and these surface charges react with applied electric fields to generate electric shear forces. By applying electric fields, the separate flow streams get mixed passing the electrodes. The micro mixing device invented in this work has simple structure and no mechanical moving part, which can provide a reliable mixing function on biochips.

Schematic illustration of the proposed active micro-mixer shown in FIG. 1. A metal electrode was deposited and patterned on a silicon wafer that was anisotropically etched. Another metal electrode was also patterned on a Pyrex glass wafer and bonded to silicon wafer using polymer bonding technique. After fabrication, two liquid samples, which have different electric conductivities, have been injected into the microchannel. The cross sectional view and basic mixing principle is shown in FIG. 2. σ₁ and σ₂ denote electric conductivities of each liquid sample. From the electromagnetic theory, surface charges are induced and accumulated on the boundary of dielectric materials, which are the liquid samples in this case. When an external electric field is applied over the surface charges, the charges will be moved with liquids due to a shear stress generated at the interface layer between the liquids to be mixed. These phenomena can continuously occur and thus the convection of the liquid samples will continue until the liquid samples get fully mixed to eliminate the interfacial shear stress. The electric force profile over the interface, which causes convection of the liquids, is plotted in FIG. 3 based on analytical analyses. The mixing speed is governed by the parameters of applied electric fields, electric properties of the liquid samples, and geometry of the electrodes. As described in FIGS. 1 and 2, the invented active micro-mixer has very simple structure without any mechanical moving part so it provides more reliable mixing performance.

In order to demonstrate the proposed mixing concepts, two different liquid samples have been chosen: one is DI water (low conductivity) and the other is saltine water (high conductivity) which was dyed for the optical monitoring. Two liquid samples have been injected through the fabricated device as shown in FIG. 4(a). With no applied electric fields, the two injected liquid samples were not mixed in the microfluidic channel as clearly showing two separate liquid streams along the microchannel. By applying electric fields to the electrodes, however, the flowing liquid samples were fully mixed after passing the electrodes due to the electric shear force generated on the interface between the liquid samples. FIG. 4(b) obviously shows the function of the invented active micro-mixer, demonstrating two separate liquid streams before reaching the electrodes and one liquid stream after passing the mixing zone. The liquid samples, which have less than 10 pl of the volume, have been successfully mixed at as low as 5 V of applied voltage across the electrodes. In addition, the active mixing function has been achieved by controlling the applied electric fields across the electrodes as clearly demonstrated in FIG. 4.

### BRIEF DESCRIPTION OF THE FIGURES

This invention, as defined in the claims, can be better understood with reference to the following drawings. The drawings are not necessarily to scale, emphasis instead being placed upon clearly illustrating principles of the present invention.

FIG. 1 is a schematic illustration of an on-chip microfluidic biochemical analysis system.

FIG. 2 is a Schematic illustration of the active microfluidic mixer.

FIG. 3 is a Cross sectional view along A-B in FIG. 2 showing the convection and mixing mechanism.

FIG. 4 is a Model and parameters for analytical calculation.

FIG. 5. The plotted electric force profile on the interface.

FIG. 6. Microphotograph of the fabricated active microfluidic mixer (upper electrode is shown from back side through the glass wafer).

FIG. 7. Mixing test results of the fabricated micro-mixer: mixing between DI water and salt-water.

FIG. 8. Minimum voltage required for mixing of the flowing DI water and salt-water solution.

### DETAILED DESCRIPTION OF THE INVENTION

As used herein, the term “detection means” refers to any means, structure or configuration that allows one to interrogate a sample within the sample-processing compartment using analytical detection techniques well known in the art. Thus, a detection means includes one or more apertures, elongated apertures or grooves which communicate with the sample processing compartment and allow an external detection apparatus or device to be interfaced with the sample processing compartment to detect an analyte passing through the compartment.

A plurality of electrical “communication paths” capable of carrying and/or transmitting electric current can be arranged adjacent to the sample processing channels or compartment such that the electrodes, in combination with the paths, form a circuit. As used herein, a communication path includes any conductive material that is capable of transmitting or receiving an electrical signal. In an exemplary embodiment, the conductive material is gold, silver, platinum or copper.

The term “laser ablation” is used to refer to a machining process using a high-energy photon laser such as an excimer laser to ablate features in a suitable substrate. The excimer laser can be, for example, of the F2, ArF, KrC1, KrF, or XeC1 type. In laser ablation, short pulses of intense ultraviolet light are absorbed in a thin surface layer of material within about 1 micron or less of the surface. Preferred pulse energies are greater than about 100 millijoules per square centimeter and pulse durations are shorter than about 1 microsecond. Under these conditions, the intense ultraviolet light photo-dissociates the chemical bonds in the material. Furthermore, the absorbed ultraviolet energy is concentrated in such a small volume of material that it rapidly heats the dissociated fragments and ejects them away from the surface of the material. Because these processes occur so quickly, there is no time for heat to propagate to the surrounding material. As a result, the surrounding region is not melted or otherwise damaged, and the perimeter of ablated features can replicate the shape of the incident optical beam with precision on the scale of about one micrometer.

Although laser ablation has been described herein using an excimer laser, it is to be understood that other ultraviolet light sources with substantially the same optical wavelength and energy density may be used to accomplish the ablation process. Preferably, the wavelength of such an ultraviolet light source will lie in the 150 nm to 400 nm range to allow high absorption in the substrate to be ablated. Furthermore, the energy density should be greater than about 100 millijoules per square centimeter with a pulse length shorter than about 1 microsecond to achieve rapid ejection of ablated material with essentially no heating of the surrounding remaining material. Laser ablation techniques are well known in the art.

The term “injection molding” is used to refer to a process for molding plastic or nonplastic ceramic shapes by injecting a measured quantity of a molten plastic or ceramic substrate into dies (or molds). In one embodiment of the present invention, devices may be produced using injection molding. More particularly, it is contemplated to form a mold or die of a device wherein excimer laser-ablation is used to define an original microstructure pattern in a suitable polymer substrate. The microstructure thus formed may then be coated by a very thin metal layer and electroplated (such as by galvano forming) with a metal such as nickel to provide a carrier. When the metal carrier is separated from the original polymer, a mold insert (or tooling) is provided having the negative structure of the polymer. Accordingly, multiple replicas of the ablated microstructure pattern may be made in suitable polymer or ceramic substrates using injection-molding techniques well known in the art.

The term “LIGA process” is used to refer to a process for fabricating microstructures having high aspect ratios and increased structural precision using synchrotron radiation lithography, galvanoforming, and plastic molding. In a LIGA process, radiation sensitive plastics are lithographically irradiated at high-energy radiation using a synchrotron source to create desired microstructures (such as channels, ports, apertures and micro-alignment means), thereby forming a primary template.

The term “chip” or “biochip” as used herein means a microfluidic system containing microdevice components on a substrate. The chip generally includes active and/or passive microvalves, fluidic components, electrical magnetic and/or pneumatic actuators, chambers, receptacles, diaphragms, detectors, sensors, ports, pumps, switches, conduits, filters, and related support systems.

The term “microfluidic” refers to a system or device having a network of chambers connected by channels, tubes or other interconnects in which the channels may act as conduits for fluids or gasses.

Microfluidic systems are particularly well adapted for analyzing small sample sizes. Sample sizes are typically are on the order of nanoliters and even picoliters. Similar apparatus and methods of fabricating microfluidic devices are also taught and disclosed in U.S. Pat. Nos. 5,858,195, 5,126,022, 4,891,120, 4,908,112, 5,750,015, 5,580,523, 5,571,410, and 5,885,470, incorporated herein by reference.

“Microfluidic analytical systems” refer to systems for forming chemical, clinical, or environmental analysis of chemical and/or biological specimens. Such microfluidic systems are generally based on a chip. These chips are preferably based on a substrate for micromechanical systems. Substrates are generally fabricated using photolithography, wet chemical etching and other techniques similar to those employed in the semiconductor industry. Microfluidic systems generally provide for flow control and physical interactions between the samples and the supporting analytical structure. The microfluidic device generally provides conduits and chambers arranged to perform numerous specific analytical operations including mixing, dispensing, valving, reactions, detections, electrophoresis and the like.

The term “substrate” is used herein to refer to any material suitable for forming a microfluidic device, such as silicon, silicon dioxide material such as quartz, fused silica, glass (borosilicates), laser ablatable polymers (including polyimides and the like), and ceramics (including aluminum oxides and the like). One or more layers of material formed from a dimensionally stable support may form the substrate. Further, the substrate may comprise composite substrates such as laminates. A “laminate” refers to a composite material formed from several different bonded layers of same or different materials. In the case of polymeric substrates, the substrate materials may be rigid, semi-rigid, or non- rigid, opaque, semi-opaque or transparent, depending upon the use for which they are intended. For example, devices that include an optical or visual detection element will generally be fabricated, at least in part, from transparent materials to allow, or at least facilitate that detection. Examples of particularly preferred polymeric materials include, e.g., polymethylmethacrylate (PMMA), polydimethylsiloxanes (PDMS), polyurethane, polyimide, polyvinylchloride (PVC), polystyrene, polysulfone, polycarbonate, and the like. Preferably, these materials will be phenolic resins, epoxies, polyesters, thermoplastic materials, polysulfones, or polyimides and/or mixtures thereof.

In addition to constructing the substrate using conventional printed circuit board composites, alternative structures can be used. For example, for certain applications the use of plastic films, metals, glasses, ceramics, injection molded plastics, polyastomeric layers, ferromagnetic layers, sacrificial photo resist layers, shaped memory metal layers, optic guiding layers, polymer based light displays or other suitable materials may be used. These may be bound with the substrate to form the system with or without an adhesive bonding layer.

In general, microfluidic devices can be fabricated out of any material that has the necessary characteristics of chemical compatibility and mechanical strength. One exemplary material is silicon since a wide range of advanced microfabrication and micromachining techniques have been developed for it and are well known in the art. Additionally, microfluidic devices can be produced directly in electrically insulating materials. The most widely used processes include isotropic wet chemical etching of glass or silica and molding of plastics. In another embodiment, the microfluidic devices can be produced as a hybrid assembly consisting of three layers—(1) a substrate, (2) a middle layer that forms the channel and/or chamber walls and whose height defines the wall height generally joined or bonded to the substrate and (3) a top layer generally joined or bonded to the top of the channels that forms a cover for the channels. In one exemplary method, the channels are defined by photolithographic techniques and etching away the material from around the channel walls produces a freestanding thin walled channel structure. Freestanding structures can be made to have very thin or very thick walls in relation to the channel width and height. The walls, as well as the top and bottom of a channel can all be of different thickness and can be made of the same material or of different materials or a combination of materials such as a combination of glass and silicon. Sealed channels or chambers can be made entirely from silicon glass and/or plastic substrates.

It should be noted that throughout the description the terms “channel” and “micro-channel” refer to structures for guiding and constraining gasses or fluids and gas or fluid flow and also include reservoir structures associates with micro-channels and will be used synonymously and interchangeably unless the text declares otherwise.

The present invention provides for an active micro-mixer using electrohydrodynamic (EHD) convection. The electrohydrodynamic fluid transport mechanism (see, e.g., U.S. Pat. Nos. 5,126,022, 5,858,199, and 5,869,004, incorporated herein by reference in their entirety), typically employs a series of electrodes disposed across one surface of a channel or reaction/mixing chamber.

The present invention provides for active microfluidic mixer device, comprising:

a) A substrate

b) at least one microfluidic channel located within the substrate;

c) at least one first electrode and at least one second electrode each in communication with at least one electrical communication path capable of providing an electrical charge; and electric potential distribution in the channel

d) wherein the first and second electrodes are disposed across the channel within 200 μm of each other and are arranged in such a manner that the electrodes are capable of providing a transverse electric field across the channel; and

e) wherein the relative position of the electrodes is fixed and fluid is capable of flowing between the electrodes.

The present invention also provides for methods of controlling fluid mixing properties within a microfluidic mixer device, comprising the steps of:

a) Arranging in a microfluidic channel at least one first electrode and at least one second electrode each in communication with at least one electrical communication path capable of providing an electrical charge;

b) Providing at least two fluids having different electric conductivities;

c) wherein the first and second electrodes are disposed across the channel within 200 μm of each other and are arranged in such a manner that the electrodes are capable of providing a transverse electric field within the fluids; and

d) applying a voltage between the electrodes to produce a mixing action of the fluids between the electrodes in a shear direction.

The surface charges are induced at the interface of the liquid samples that have different electric conductivities or different electric permittivities, and these surface charges react with the applied electric fields to generate electric shear forces. Films made from copper, silver, gold, indium, tin, nickel and oxides and alloys thereof may be particularly suited for patterning electrodes on substrate surfaces, e.g., a glass, polymer, or silicon substrate.

By applying electric fields, the separate flow streams get mixed passing the electrodes. The micro-mixing device of the present invention has simple structure and no mechanical moving part, which can provide a reliable mixing function on biochips.

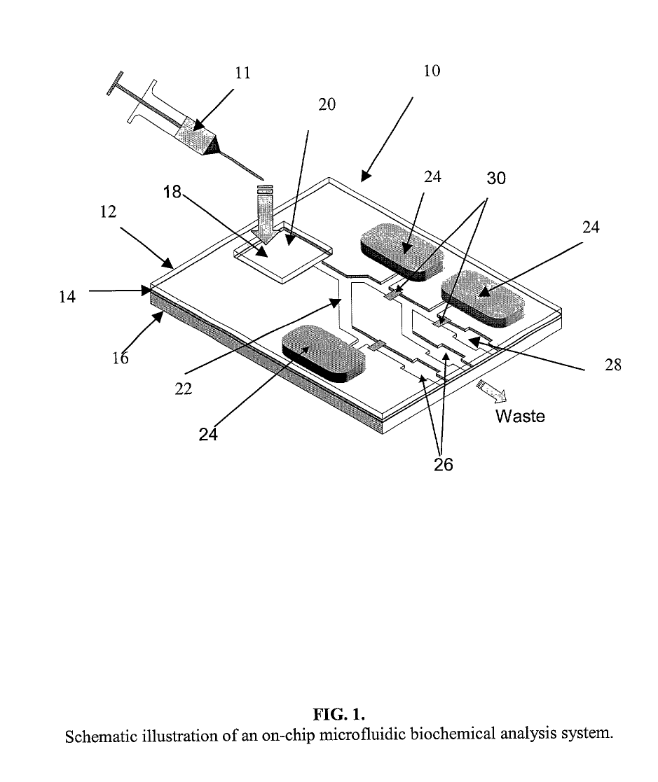

Schematic illustration of a biochip microfluidic biochemical analysis device 10 is shown in FIG. 1. Typically, the device 10 comprises a substrate 16 upon which is layered one or more layers 12 and 14 to create microchannels, reservoirs, chambers, etc. In a typical analysis system, a biofluid sample 18 is added to a sample reservoir 20 by an inlet port or injection port 11. The biosample 11 is directed through a microchannel network 22 of the device where it is mixed with one or more reagents. Such reagents may be added from inlet ports or be stored within the chip itself in reagent reservoirs 24. The biofluid and reagent(s) flow past the active micro-mixer 30 where the fluids are mixed and delivered to one ore more reaction or detection chambers 26. Optionally, the fluids can be directed to a waste reservoir or other exit outlet 28.

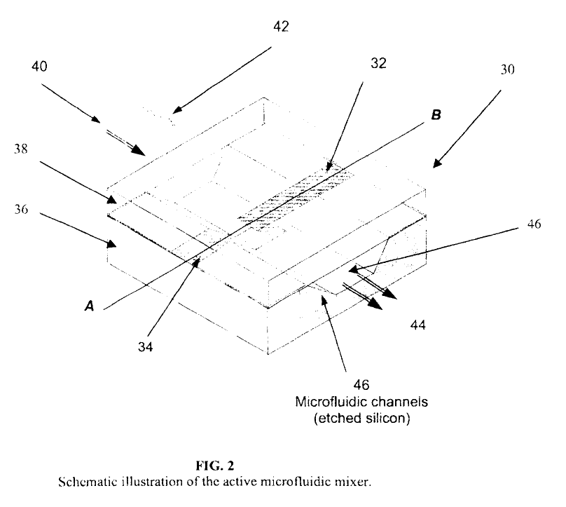

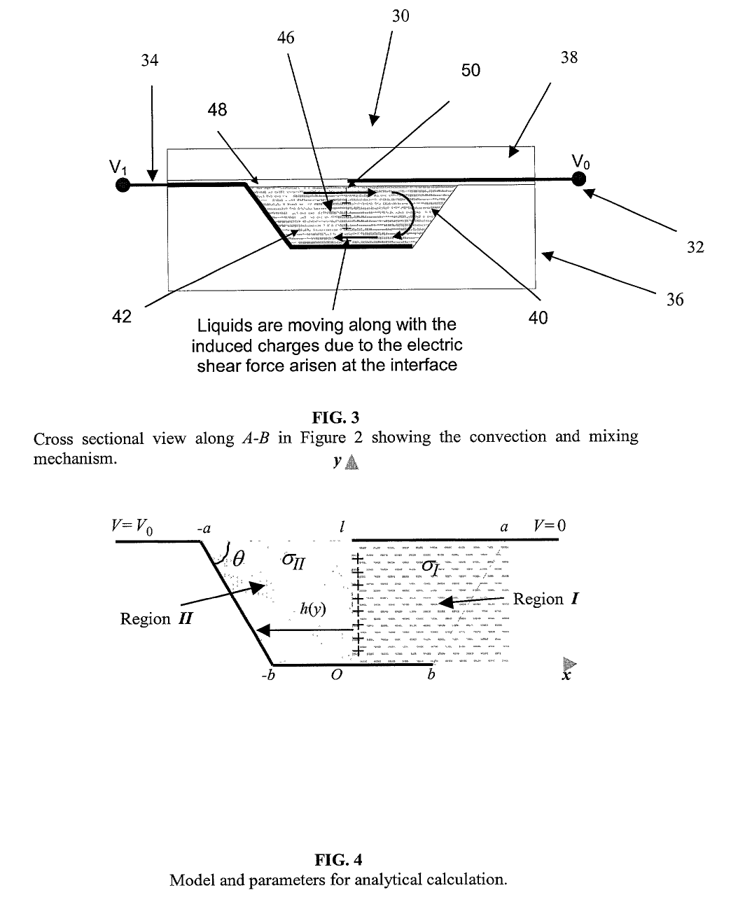

The active micro-mixer 30 of such a device is shown schematically in FIG. 2. A first metal electrode 34 is generally deposited and patterned on a silicon wafer 36 that was anisotropically etched or on a glass wafer 36 that was isotropically etched. A second metal electrode 32 is patterned on a glass wafer 38 and bonded to glass or silicon wafer 36 using polymer bonding layer 48 technique. After fabrication, two liquid samples 40 and 42, which have different electric conductivities and/or permittivities, are directed into the microchannel 46. The cross sectional view and basic mixing principle is shown in FIG. 3 wherein the first fluid 40 has an electric conductivity σ₁ and the second fluid has a electric conductivity σ₂. From the electromagnetic theory, surface charges are induced and accumulated on the boundary of dielectric materials 50, which are the liquid samples in this case. When an external electric field is applied over the surface charges, the charges will be moved with liquids due to a shear stress generated at the interface layer between the liquids to be mixed. These phenomena can continuously occur and thus the convection of the liquid samples 40 and 42 will continue until the liquid samples get fully mixed to eliminate the interfacial shear stress. The electric force profile over the interface, which causes convection of the liquids, is plotted in FIG. 5 based on analytical analyses. The mixing speed is governed by the parameters of applied electric fields (V₀ and V₁), electric properties of the liquid samples, and geometry of the electrodes. As described in FIGS. 2 and 3, the active micro-mixer has very simple structure without any mechanical moving part so it provides more reliable mixing performance.

Generally, the device 10 contains a number of reagent inlets, reaction or detection chambers 26, sample reservoirs 20 and sample inlets 11.

The reagent inlets may be used to introduce buffers or water into the analytical element.

The device of the present invention may also incorporate one or more microvalves for controlling the direction of fluid flow within the device. Examples of valves that may be used in the device are described in, e.g., U.S. Pat. No. 5,277,556, incorporated herein by reference.

The device may also incorporate one or more filters for removing debris and solids from the sample. The filters may generally be within the apparatus, e.g., within the microfluidic channels 22 leading from the sample reservoir 20. A variety of well known filter media may be incorporated into the device, including, e.g., cellulose, nitrocellulose, polysulfone, nylon, vinyl/acrylic copolymers, glass fiber, polyvinylchloride, and the like. Similarly, separation chambers having a separation media, e.g., ion exchange resin, affinity resin or the like, may be included within the device to eliminate contaminating proteins, etc.

The device of the present invention may also contain one or more sensors within the device itself to monitor the progress of one or more of the operations of the device. For example, optical sensors and pressure sensors may be incorporated into one or more reaction chambers to monitor the progress of the various reactions, or within flow channels to monitor the progress of fluids or detect characteristics of the fluids, e.g., pH, temperature, fluorescence and the like. Reagents used within the device may be exogenously introduced into the device, e.g., through sealable inlets in each respective reservoir.

However, these reagents may be predisposed within the device. For example, these reagents may be disposed within reagent reservoirs 24 or within the microfluidic channels 22 leading to the reaction or detection chambers 26. Preferably, the reagents may be disposed within reservoirs adjacent to and fluidly connected to their respective reaction or detection chambers, whereby the reagents can be readily transported to the appropriate chamber as needed.

EHD micro-mixers have typically been viewed as suitable for moving fluids of extremely low conductivity, e.g., 10⁻¹⁴ to 10⁻⁹ S/cm. However, broad range of solvents and solutions can be mixed using appropriate solutes than facilitate mixing, using appropriate electrode spacings and geometries, or using appropriate pulsed, AC or DC voltages to power the electrodes.

The present invention employs both low and high conductivity fluids in the same microchannel, to affect the mixing of the subject fluids.

Specifically, the subject fluids are generally provided having a first fluid having a low relative conductivity, and dispensed as a discrete volume or fluid region, into a microscale channel, along with a second fluid of high relative conductivity. The fluid of high relative conductivity will typically have a conductivity that is at least two times the conductivity of the low relative conductivity fluid, and preferably, at least five times the conductivity of the low relative conductivity fluid, more preferably at least ten times the conductivity of the low relative conductivity fluid, and often at least twenty times the conductivity of the low relative conductivity fluid.

Typically, the low conductivity fluid will have a conductivity in the range of from about 0.01 mS to about 500 mS, preferably from about 0.05 mS to about 100 mS, and more preferably from about 0.1 mS to about 10 mS. The high conductivity fluid typically has a conductivity in the range of from about 0.02 mS to about 1000 mS, preferably from about 0.05 mS to about 500 mS, and more preferably from about 0.2 mS to about 200 mS.

The electrodes used in the liquid distribution system described below preferably have a width from about 25 microns to about 100 microns, more preferably from about 50 microns to about 75 microns. Preferably, the electrodes protrude from the top of a channel to a depth of from about 5% to about 95% of the depth of the channel, more preferably from about 25% to about 50% of the depth of the channel. Usually, as a result the electrodes, defined as the elements that interact with fluid, are from about 5 microns to about 95 microns in length, preferably from about 25 microns about to 50 microns.

Preferably, the micro-mixer includes a first electrode and a second electrode that are preferably spaced from about 1 microns to about 250 microns apart, more preferably, from about 2.5 microns to about 100 microns apart, yet more preferably from about 5 microns to about 75 microns apart, or, in an alternate embodiment, from about 10 microns to about 50 microns apart.

The voltages used across the first and second electrodes when the micro-mixer is operated in pulsed, AC or DC mode are typically from about 0.1 V to about 200 V, preferably from about 1 to about 100 V, more preferably ably from about 2 to about 50 V, yet more preferably from about 5 V to about 30 V.

The voltages used across the first and second electrodes when the micro-mixer is operated are generally at a frequency from about 0.1 Hz to about 1 MHz, preferably at a frequency from about 1 Hz to 0.5 MHz, and more preferably at a frequency from about 1 Hz to 1 kHz.

As will be recognized in the art, depending on electric properties of the fluids, a pulsed, AC or DC current can be applied to achieve maximum mixing capability.

Another, procedure that can be applied is to use a number of electrodes, typically evenly spaced, and to use a travelling wave protocol that induces a voltage at each pair of adjacent electrodes in a timed manner that first begins to apply voltage to the first and second electrodes, then to the second and third electrodes, etc.

Another aspect of mixing is the observation that fluids that are resistant to mixing at a reasonable field strength can be made more susceptible to electrode-based mixing by adding a suitable mixing additive. Preferably, the mixing additive is miscible with the resistant fluid and can be mixed at high pressure, P, high flow rate, Q, and good electrical efficiency, h (i.e., molecules mixed per electron of current). Generally, the mixing additive comprises from about 0.05% w/w to about 10% w/w of the resulting mixture, preferably from about 0.1% w/w to about 5% w/w, more preferably from about 0.1% w/w to about 1% w/w. In all cases, mixing additives are selected on the basis of their mixing characteristics and their compatibility with the chemistries or other processes sought to be achieved in the liquid distribution system.

To power the electrode-based micro-mixers, one or more digital drivers, consisting of, for example, a shift register, latch, gate and switching device, such as a DMOS transistor, permits simplified electronics so that fluid flow in each of the channels can be controlled independently. Preferably, each digital driver is connected to multiple switching devices that each can be used to control the mixing rate of a separate electrode-based micro-mixer.

The liquid distribution systems of the invention can be constructed a support material that is, or can be made, resistant to the chemicals sought to be used in the chemical processes to be conducted in the device. For all of the above-described embodiments, the preferred support material will be one that has shown itself susceptible to microfabrication methods that can form channels having cross-sectional dimensions between about 50 microns and about 250 microns, such as glass, fused silica, quartz, silicon wafer or suitable plastics. Glass, quartz, silicon and plastic support materials are preferably surface treated with a suitable treatment reagent such as chloromethylsilane or dichlorodimethylsilane, which minimize the reactive sites on the material, including reactive sites that bind to biological molecules such as proteins or nucleic acids. As discussed earlier, the expansion valve liquid distribution system is preferably constructed of a plastic. In embodiments that require relatively densely packed electrical devices, a non-conducting support material, such as a suitable glass, is preferred. Coming 211-borosilicate glass, Coming 7740-borosilicate glass, available from Coming Glass Co., Coming, N.Y., are among the preferred glasses.

For the purposes of this application, positive (+) flow shall be flow in the direction of the negative electrode, and negative (−) flow shall be flow in the direction of the positive electrode. While not wishing to be restricted to theory, several theoretical concepts are believed to play a role in the mechanics of EHD mixing. FIG. 3 shows simple working principle of the proposed active micro-mixer using EHD convection. From electromagnetic theory, surface charges are induced and accumulate on the boundary of dielectric materials, which are the liquid samples in this case. When an external electric field is applied over the surface charges, these charges will move with the liquids due to a shear force generated at the interface layer between the liquids to be mixed. These reactions can occur continuously and thus the convection of the liquid samples will continue until the liquid samples get filly mixed to eliminate the interfacial shear stress. The mixing speed is governed by the parameters of applied electric fields, electrical properties like conductivity, and geometry of the electrodes. All these processes can be understood analytically for the ideal case.

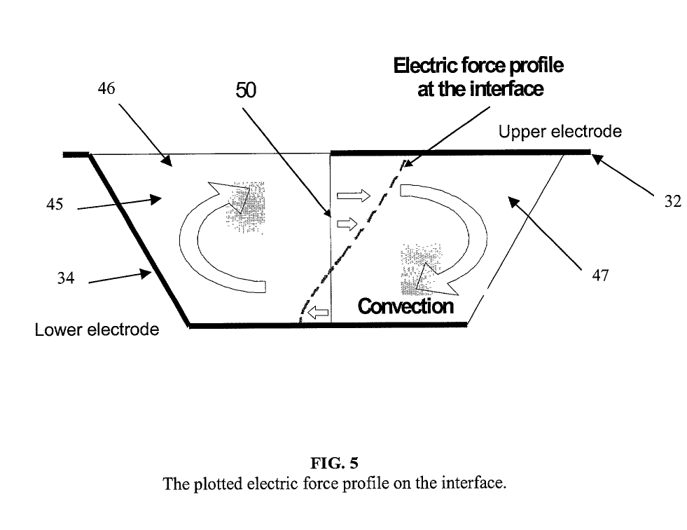

The parameters and geometry of the device are defined in FIG. 4. Each region indicates two different liquid samples, which have different conductivities. σ_{I} and σ_{II} denote the conductivities of liquid I and liquid II, respectively.

In the region I, we assume that y-directional electric fields can be described as

$${E}_{y}^{I} = \frac{{V}_{0}}{l} {y}^{⋒} , \qquad ( 1 )$$

where V₀ is the applied voltage and l is the depth.

From continuity condition of the tangential component of electric fields at the boundary of the dielectric materials, y-directional electric fields near the interface in the region II can be written as

$${E}_{y}^{II} = \frac{{V}_{0}}{l} {y}^{⋒} \qquad ( 2 )$$

The interface assumes a distribution in electrical potential that varies from zero at the upper electrode to V₀ at the lower electrode. Because the upper electrode has zero potential, with a spacing h(y) that varies linearly with y, there is a surface charge induced on the interface. Hence, the distribution of potential at the interface is

$${Φ \vert}_{x = 0} = \frac{{V}_{0}}{l} ( l - y ) , \qquad ( 3 )$$

and h(y), the distance from lower electrode to the interface, is

h(y)=cotθ·y+b=a−cotθ (l−y). (4)

In the region II, therefore, the x-directional electric field is

$${E}_{x}^{II} = - ∇ Φ = \frac{{V}_{0}}{l} \cdot \frac{y}{a - cot θ \cdot ( l - y )} \hat{x} . \qquad ( 5 )$$

To obtain x-directional electric fields near the interface in the region I, the continuity condition of the normal current density at the interface

$$\hat{n} \cdot ( {σ}_{II} {E}^{II} - {σ}_{I} {E}^{I} ) = 0 \qquad ( 6 )$$

is used. Then, the Eₓ^{I} is described as

$${E}_{x}^{I} = \frac{{σ}_{II}}{{σ}_{I}} {E}_{x}^{II} = \frac{{σ}_{II} {V}_{0} y}{{σ}_{I} l [ a - ( l - y ) cot θ ]} \hat{x} . \qquad ( 7 )$$

Maxwell stress tensor at the interface is given as

$${T}_{ij} = ϵ ( {E}_{i} {E}_{j} - \frac{1}{2} {δ}_{ij} {E}_{k} {E}_{k} ) , \qquad ( 8 )$$

where δᵢⱼ is Kronecker delta.

With these equations, we can derive x-directional shear stress at the interface

$${T}_{xx} = \frac{ϵ}{2} ( \frac{{σ}_{II} {V}_{0}^{2} {y}^{2}}{{σ}_{I} {{l}^{2} [ a - ( l - y ) cot θ ]}^{2}} - \frac{{V}_{0}^{2}}{{l}^{2}} ) . \qquad ( 9 )$$

The electric force on the interface can be obtained by surface integral of the shear stress. Although we only calculated the x-directional shear stress, y-directional forces also exist along the interface of the liquids.

From Equation (9), the force on the interface is determined by applied voltage (V₀), depth of the channel (l), width of the channel (a), and the ratio of the conductivity of the liquid samples (σ_{II}/σ_{I}). The electric force profile varies along the interface and the liquids in the microchannel are assumed incompressible, so the imbalance between top and bottom of the channel along the interface causes clockwise convection in the channel and the two liquid samples will be mixed as shown in FIG. 5.

For the case of liquid/microparticle mixing, since the microparticles are usually dispersed in a specific buffer solution, and the liquid that contains reagents or bio-molecules has different pH number, the microparticles get mixed with reagents as two liquid samples are mixed.

The following references, to the extent that they provide exemplary procedural or other details supplementary to those set forth herein, are specifically incorporated herein by reference: U.S. Pat. Nos. 6,197,595, 6,168,948, 6,120,665, 6,116,257, 5,964,997, 5,961,800, and 5,958,344.

### EXAMPLES

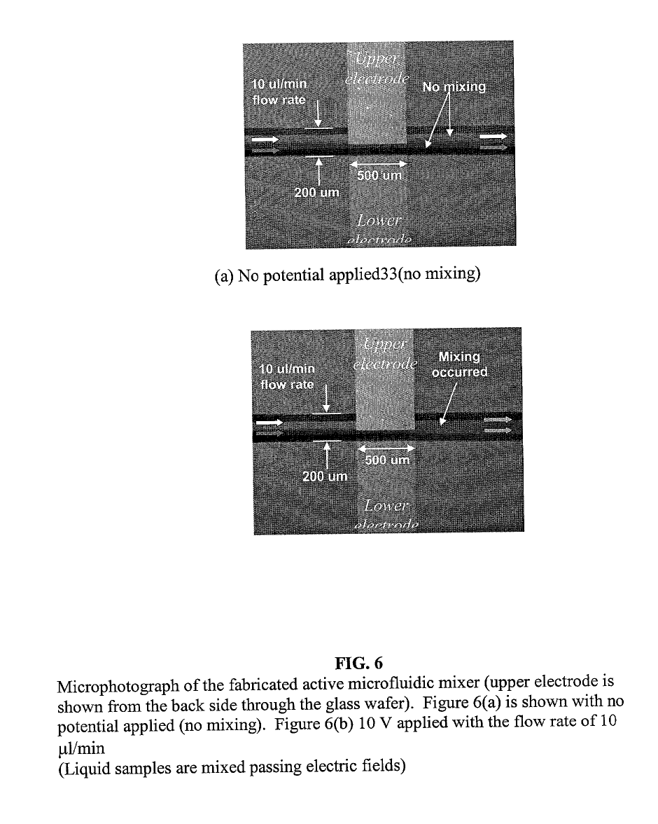

In order to demonstrate the proposed mixing concepts, two different liquid samples have been chosen: one is DI water (low conductivity) and the other is saltine water (high conductivity) which was dyed for the optical monitoring. Two liquid samples have been injected through the fabricated device as shown in FIG. 6(a). With no applied electric fields, the two injected liquid samples were not mixed in the microfluidic channel as clearly showing two separate liquid streams along the microchannel. By applying electric fields to the electrodes, however, the flowing liquid samples were fully mixed after passing the electrodes due to the electric shear force generated on the interface between the liquid samples. FIG. 6(b) obviously shows the function of the invented active micro-mixer, demonstrating two separate liquid streams before reaching the electrodes and one liquid stream after passing the mixing zone. The liquid samples, which have less than 10 pl of the volume, have been successfully mixed with less than 5 V of applied voltage across the electrodes. In addition, the active mixing function has been achieved by controlling the applied electric fields across the electrodes as clearly demonstrated in FIG. 6.

The (100) silicon wafer was patterned and anisotropically etched in potassium hydroxide solution to create a microchannel for the device.

The width and depth of the microchannel are 200 μm and 60 μm, respectively. After the etching process, the silicon wafer was oxidized for electrical isolation and the electrodes (Cr 300 Å/Au 3000 Å) were deposited and patterned on both silicon and glass wafer. The glass wafer was coated with a Teflon-like thin film to isolate the upper electrode from direct contact to the high conductivity liquid samples. Finally, the two wafers were bonded using the Teflon-like film as a bonding layer. The fabricated device is shown in FIG. 6.

To demonstrate the mixing, two different liquid samples were chosen: DI water (low conductivity) and salt-water (high conductivity). A dye was added to the salt-water for optical monitoring.

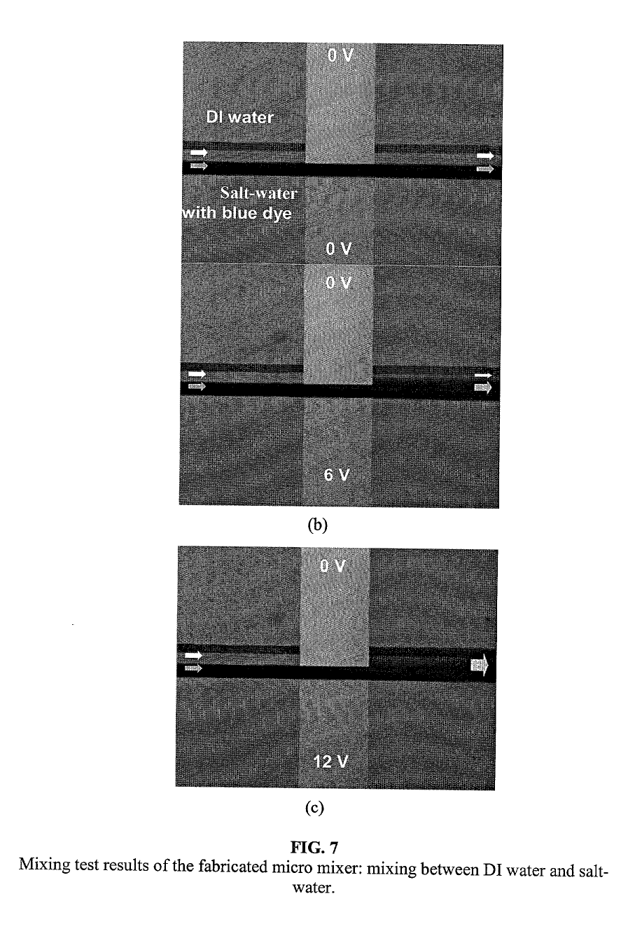

Two liquid samples were injected through the fabricated device as shown in FIG. 7(a). With no applied electric field, the two injected liquid samples were not mixed in the microfluidic channel as seen clearly in FIG. 7(a) from the two separate liquid streams. By applying electric field to the electrodes, however, the flowing liquid samples were fully mixed after passing the electrodes, due to the electric shear force generated at the interface between the liquid samples. As shown in FIG. 7(b), the liquid streams were deformed due to the external electric field across the microfluidic channel. FIG. 7(c) obviously shows the functionality of the realized active microfluidic mixer, clearly demonstrating two separate liquid streams before reaching the electrodes and only one liquid stream after passing the mixing zone.

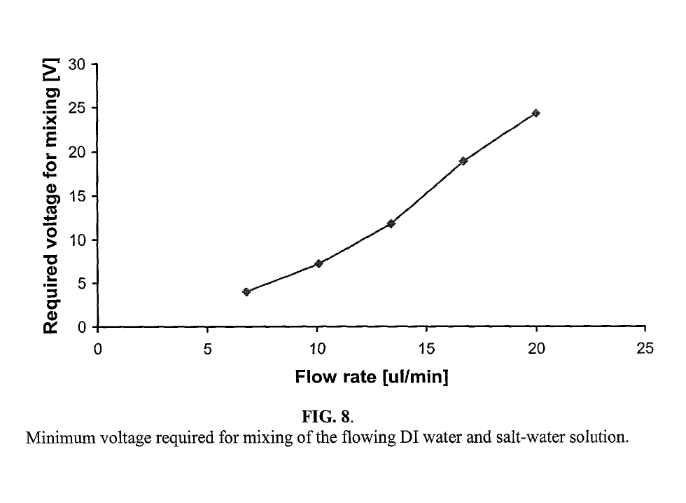

For a given geometry of the device and with the selected liquid samples, the mixing speed and capability of the mixer depends on the strength of the applied electric fields and the flow rate of the samples. FIG. 8 shows the characteristics of the micro-mixer by measuring the voltage at which the flowing liquid samples get mixed. At a flow rate of 10 μL/min, two fluids are mixed with a low mixing voltage of 7 V.

The excellent mixing performance of the proposed active micro-mixer has been demonstrated using salt-water solution and DI water. However, the mixing of the solutions, which have very similar low conductivities, was not successfully achieved with such as DI water and isopropyl alcohol sets. When we used very high conductivity aqueous solutions or operated the mixing device at very low flow rate, we could observe the electrodes to be occasionally electrolyzed because the electrodes were exposed to the relatively high electric current once mixing begins. So further research on the dynamic characteristics related to conductivity of the solutions and voltage levels are now under investigation in addition to the structural optimization of the device.

Although the present invention has been discussed with respect to the preferred and alternative embodiments, it will be apparent to those skilled in the art that the present invention is not limited to these embodiments. Therefore, a person of ordinary skill in the art will understand that variations and modifications of the present invention are within the spirit and scope of the present invention.

1. An active microfluidic mixer device, comprising:
a) A substrate
b) at least one microfluidic channel located within the substrate;
c) at least one first electrode and at least one second electrode each in communication with at least one electrical communication path capable of providing an electrical charge; and electric potential distribution in the channel
d) wherein the first and second electrodes are disposed across the channel within 200 μm of each other and are arranged in such a manner that the electrodes are capable of providing a transverse electric field across the channel; and
e) wherein the relative position of the electrodes is fixed and fluid is capable of flowing between the electrodes.

2. The device of claim 1, wherein the substrate is made from a material selected from the group consisting of silicon, quartz, silica, glass, laser ablatable polymer, injection molded polymer, embossed polymer, and ceramic.

3. The device of claim 2, wherein the device further comprises one or more additional components selected from the group consisting of reagent inlets, detection chambers, sample reservoirs, waste outlets and sample inlets.

4. The device of claim 3, wherein the device further electrodes are comprised of a metal selected from the group consisting of copper, silver, gold, indium, tin, nickel and oxides and alloys.

5. The device of claim 4, wherein the device further comprises one or more sensors.

6. The device of claim 4, wherein the device further comprises one or more filters.

7. The device of claim 4, wherein the electrode are powered by one or more digital drivers.

8. The device of claim 7, wherein the digital driver consisting of a shift register, a latch, a gate and a switching device.

9. The device of claim 4, wherein the first electrode and a second electrode are preferably spaced from about 1 microns to about 250 microns apart.

10. The device of claim 4, wherein the first electrode and a second electrode are preferably spaced from about 2.5 microns to about 100 microns apart.

11. The device of claim 4, wherein the first electrode and a second electrode are preferably spaced from about 5 microns to about 75 microns apart.

12. The device of claim 4, wherein the voltages used across the first and second electrodes when the micro-mixer is operated is from about 0.1 V to about 200 V.

13. The device of claim 4, wherein the voltages used across the first and second electrodes when the micro-mixer is operated is from about 1 to about 100 V.

14. The device of claim 4, wherein the voltages used across the first and second electrodes when the micro-mixer is operated is from about 2 to about 50 V.

15. The device of claim 4, wherein the voltages used across the first and second electrodes when the micro-mixer is operated is from about 5 V to about 30 V.

16. The device of claim 4, wherein the voltages used across the first and second electrodes when the micro-mixer is operated is selected from the group consisting of DC, sine wave AC, and square wave AC.

17. The device of claim 16, wherein the voltages used across the first and second electrodes when the micro-mixer is operated is at a frequency from about 0.1 Hz to about 1 MHz.

18. The device of claim 16, wherein the voltages used across the first and second electrodes when the micro-mixer is operated is at a frequency from about 1 Hz to 1 kHz.

19. An method of controlling fluid mixing properties within a microfluidic mixer device, comprising the steps of:
a) Arranging in a microfluidic channel at least one first electrode and at least one second electrode each in communication with at least one electrical communication path capable of providing an electrical charge;
b) Providing at least fluids having different electric conductivities;
c) wherein the first and second electrodes are disposed across the channel within 200 μm of each other and are arranged in such a manner that the electrodes are capable of providing a transverse electric field within the fluids; and
d) applying a voltage between the electrodes to produce a mixing action of the fluids between the electrodes in a shear direction.

20. The method of claim 19, wherein the microfluidic channel is disposed on a substrate made from a material selected from the group consisting of silicon, quartz, silica, glass, polymer, and ceramic.

21. The method of claim 20, wherein the method further comprises one or more additional components selected from the group consisting of reagent inlets, detection chambers, sample reservoirs, waste outlets and sample inlets.

22. The method of claim 21, wherein the electrodes are comprised of a metal selected from the group consisting of copper, silver, gold, indium, tin, nickel and oxides and alloys.

23. The method of claim 21, further comprising directing the mixed fluid to a detection chamber in communication with one or more sensors.

24. The method of claim 21, further comprising filtering at least one of the fluids.

25. The method of claim 21, further comprising the step of using a controller for controlling the voltage across the electrodes and for directing the speed of fluid mixing.

26. The method of claim 25, wherein the controller further comprises a microprocessor control interface and a detection system.

27. The method of claim 21, wherein the first electrode and a second electrode are preferably spaced from about 1 microns to about 250 microns apart.

28. The method of claim 21, wherein the first electrode and a second electrode are preferably spaced from about 2.5 microns to about 100 microns apart.

29. The method of claim 21, wherein the first electrode and a second electrode are preferably spaced from about 5 microns to about 75 microns apart.

30. The method of claim 21, wherein the voltages used across the first and second electrodes is from about 0.1 V to about 200 V.

31. The method of claim 21, wherein the voltages used across the first and second electrodes is from about 1 to about 100 V.

32. The method of claim 21, wherein the voltages used across the first and second electrodes is from about 2 to about 50 V.

33. The method of claim 21, wherein the voltages used across the first and second electrodes is from about 5 V to about 30 V.

34. The method of claim 21, wherein the voltages used across the first and second electrodes is selected from the group consisting of pulsed, DC, sine wave AC, and square wave AC.

35. The method of claim 34, wherein the voltages used across the first and second electrodes is at a frequency from about 0.1 Hz to about 1 MHz.

36. The method of claim 34, wherein the voltages used across the first and second electrodes is at a frequency from about 1 Hz to 1 kHz.

37. The method of claim 34, wherein the fluid of highest conductivity is at least twice as great as the fluid of lowest conductivity.

38. The method of claim 34, wherein the fluid of highest conductivity is at least five times greater as the fluid of lowest conductivity.

39. The method of claim 34, wherein the fluid of highest conductivity is at ten times greater as the fluid of lowest conductivity.
